(19) United States
(12) Patent Application Publication
(10) Pub. No.: US 2026/0231773 A1
(43) Pub. Date: Aug. 6, 2026

(54) SEMICONDUCTOR DEVICE INCLUDING A GUARD RING STRUCTURE

(71) Applicant: SK hynix Inc., Gyeonggi-do (KR)

(72) Inventor: Heon Yong CHANG, Gyeonggi-do (KR)

(21) Appl. No.: 19/325,532

(22) Filed: Sep. 11, 2025

(30) Foreign Application Priority Data
Feb. 3, 2025 (KR) 10-2025-0013077

(51) Int. Cl. H01L 23/00; H01L 23/58; H10B 12/00

(52) U.S. Cl. CPC H10W 42/121; H10B 12/315; H10B 12/50; H10W 42/00

(57) ABSTRACT

A semiconductor device includes a cell structure disposed in a cell area, the cell structure including a buried gate line disposed in a substrate; and a guard ring structure disposed in a guard ring area to surround the cell structure. The buried gate line includes a buried gate electrode disposed in a lower portion of a buried gate trench disposed in the substrate; and a buried gate capping layer disposed in an upper portion of the buried gate trench. The guard ring structure includes a guard ring buried interconnection line disposed in the substrate; a guard ring lower plug disposed over the substrate and electrically connected to the guard ring buried interconnection line; and a guard ring top pad disposed over the guard ring lower plug and electrically connected to the guard ring lower plug.

### CROSS-REFERENCE TO RELATED APPLICATIONS

This patent document claims priority under 35 U.S.C. 119(a) to Korean Patent Application No. 10-2025-0013077, filed on Feb. 3, 2025, which is incorporated herein by reference in its entirety.

### TECHNICAL FIELD

Embodiments of the present disclosure relate to a semiconductor device having a guard ring structure.

### BACKGROUND

Guard ring structures are protective structures in semiconductor devices, used to prevent physical damage and moisture penetration of the semiconductor devices. However, due to physical stress that occurs during the manufacturing processes for semiconductor devices, the guard ring structure may be cut and separated, and moisture may penetrate the semiconductor device.

### SUMMARY

An embodiment of the present invention provides a guard ring structure configured to enhance physical adhesion and to prevent moisture penetration.

An embodiment of the present disclosure provides a semiconductor device including a guard ring structure having a buried interconnection line.

An embodiment of the present disclosure provides a method of manufacturing a semiconductor device including a guard ring structure with a buried interconnection line.

In accordance with an embodiment of the present disclosure, a semiconductor device includes a cell structure disposed in a cell area, the cell structure including a buried gate line disposed in a substrate; and a guard ring structure disposed in a guard ring area to surround the cell structure. The buried gate line includes a buried gate electrode disposed in a lower portion of a buried gate trench disposed in the substrate; and a buried gate capping layer disposed in an upper portion of the buried gate trench. The guard ring structure includes a guard ring buried interconnection line disposed in the substrate; a guard ring lower plug disposed over the substrate and electrically connected to the guard ring buried interconnection line; and a guard ring top pad disposed over the guard ring lower plug and electrically connected to the guard ring lower plug. The guard ring buried interconnection line includes a guard ring buried electrode disposed in a lower portion of a guard ring trench disposed in the substrate; and a guard ring buried capping layer disposed in an upper portion of the guard ring trench.

In accordance with an embodiment of the present disclosure, a semiconductor device includes a cell structure, a peripheral transistor structure, an inner guard ring structure, an outer guard ring structure, and a guard ring dummy gate electrode. The cell structure includes a buried gate line disposed in a substrate. The peripheral transistor structure includes a peripheral gate electrode disposed over the substrate; a peripheral lower contact plug disposed over the substrate adjacent to one side of the peripheral gate electrode; and a peripheral interconnection line disposed over the peripheral lower contact plug. The inner guard ring structure includes inner guard ring buried interconnection lines disposed in the substrate; inner guard ring lower plugs disposed over the substrate and respectively connected to the inner guard ring buried interconnection lines; and an inner guard ring top pad disposed over the inner guard ring lower plug and electrically connected to the inner guard ring lower plugs. The outer guard ring structure includes outer guard ring buried interconnection lines disposed in the substrate; outer guard ring lower plugs disposed over the substrate and respectively connected to the outer guard ring buried interconnection lines; and an outer guard ring top pad disposed over the outer guard ring lower plugs and electrically connected to the outer guard ring lower plugs. The guard ring dummy gate electrode is disposed over the substrate between the inner guard ring structure and the outer guard ring structure.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a wafer according to an embodiment of the present disclosure, and FIG. 1B is an enlarged view of the area A of FIG. 1A.

FIGS. 2A to 2C are layouts of a portion of the guard ring area, a portion of the cell areas, and a portion of the peripheral circuit areas of the semiconductor device according to embodiments of the present disclosure.

FIGS. 3A to 3C are longitudinal cross-sectional views schematically illustrating a guard ring structure, a cell structure, and a peripheral transistor structure of a semiconductor device according to an embodiment of the present disclosure.

FIGS. 4A to 4D are longitudinal cross-sectional views schematically illustrating guard ring structures of semiconductor devices according to embodiments of the present disclosure.

FIGS. 5A and 5B are longitudinal cross-sectional views taken along the line IV-IV′ or V-V′ of FIG. 2A to describe the inner or outer guard ring structures according to an embodiment of the present disclosure.

FIGS. 6A to 6C, 7A to 7C, 8A to 8C, 9A to 9C, 10A to 10C, 11A to 11C, 12A to 12C, 13A to 13C, 14A to 14C, 15A to 15C, 16A to 16C, 17A to 17C, 18A to 18C, 19A to 19C, and 20A to 20C are longitudinal cross-sectional views illustrating methods of manufacturing semiconductor devices according to embodiments of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,”“left,” “right,”“column,”“row,”“level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

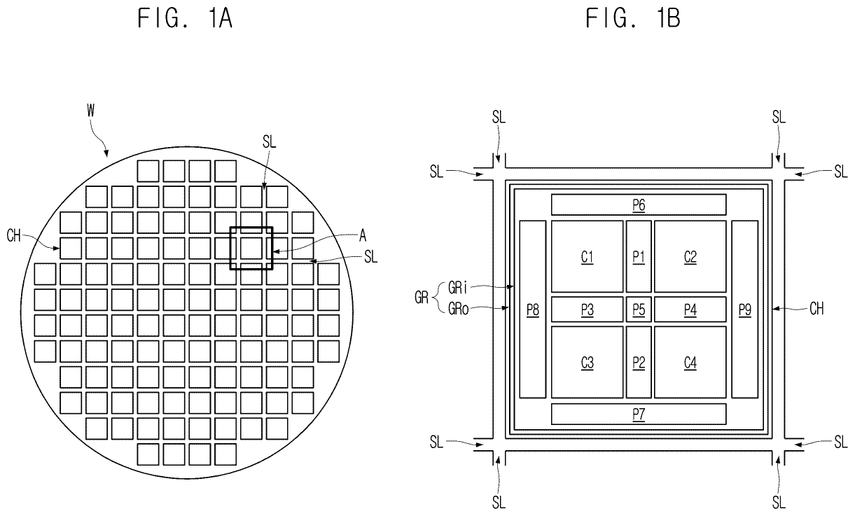

FIG. 1A is a wafer W according to an embodiment of the present disclosure, and FIG. 1B is an enlarged view of the area A of FIG. 1A. Referring to FIGS. 1A and 1B, the wafer W may include a plurality of semiconductor chips CH arranged in a matrix form (or a grid form), for example, within the boundary, shown in this instance as circular, of the wafer.

The plurality of semiconductor chips CH may be separated by grid-shaped scribe lanes SL. Each of the semiconductor chips CH may include cell areas C1 to C4, peripheral circuit areas P1 to P9, and a guard ring area GR. The cell areas C1 to C4 may be arranged in a matrix form. A plurality of memory cells may be disposed in each of the cell areas C1 to C4. Peripheral circuit areas P1 to P9 may be disposed around or between the cell areas C1 to C4. The peripheral circuit areas P1 to P9 as shown in FIG. 1B may indicate positions that peripheral circuits can be disposed. For example, at least one of the peripheral circuit areas P1 to P9 may be selectively disposed in at least one of an upper portion, a lower portion, a left portion, and/or a right portion of the cell areas C1 to C4, or spaces between the cell areas C1 to C4. The guard ring area GR may be disposed to surround the cell areas C1 to C4 and the peripheral circuit areas P1 to P9. An inner guard ring GRi and an outer guard ring GRo may be disposed in the guard ring area GR.

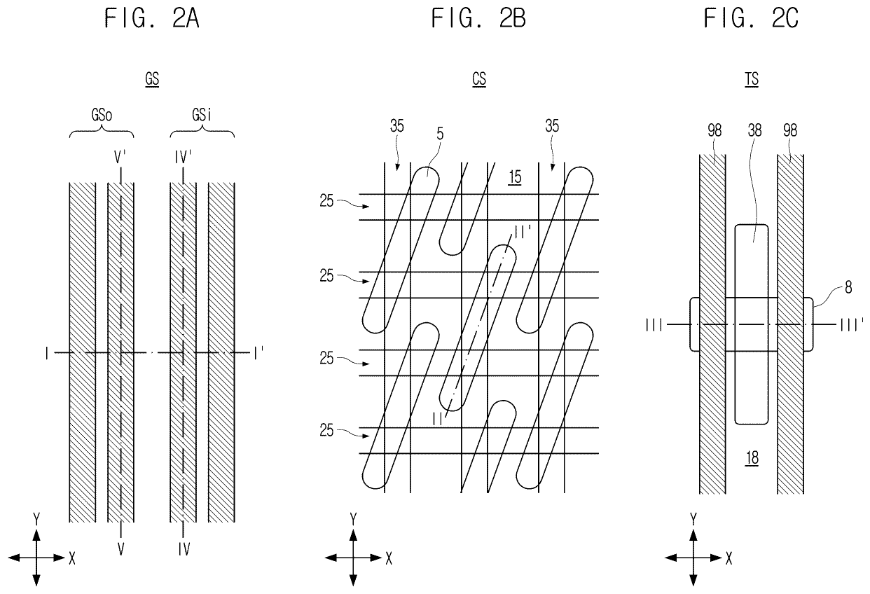

FIGS. 2A, 2B, and 2C layout, respectively, a portion of the guard ring area GR, a portion of the cell areas C1 to C4, and a portion of the peripheral circuit areas P1 to P9 of the semiconductor device. Referring to FIGS. 2A to 2C respectively, the semiconductor device may include a guard ring structure GS in the guard ring area GR, a cell structure CS in at least one of the cell areas C1 to C4, and a peripheral transistor structure TS in at least one of the peripheral circuit areas P1 to P9.

The guard ring structure GS, as shown in FIG. 2A, may include an inner guard ring structure GSi and an outer guard ring structure GSo. Each of the inner guard ring structure GSi and the outer guard ring structure GSo may include a plurality of guard rings disposed adjacent to each other in a first horizontal direction X and extending parallel to each other in a second horizontal direction Y. The first horizontal direction X and the second horizontal direction Y may be perpendicular to each other.

The cell structure CS, as shown in FIG. 2B, may include cell active regions 5, buried gate lines 25, and bit lines 35. The cell active regions 5 may be defined by a cell isolation region 15 (e.g., a cell shallow trench isolation region). Each of the cell active regions 5 may have a diagonally disposed (with respect to the matrix) elongated segment shape (for example, a rounded rectangle). The buried gate lines 25 may extend parallel to each other to cross the cell active regions 5 in the first horizontal direction X. Two of the buried gate lines 25 may cross one of the cell active regions 5 (or, in other words, each of the cell active regions 5 may be crossed by two of the buried gate lines 25). The buried gate lines 25 may correspond to cell word lines. The bit lines 35 may extend parallel to each other to cross a central portion of each of the cell active regions 5 in the second horizontal direction Y.

The peripheral transistor structure TS, as shown in FIG. 2C, may include a peripheral active region 8, a peripheral gate electrode 38, and peripheral interconnection lines 98. The peripheral active region 8 may be defined by a peripheral isolation region 18 (e.g., a peripheral shallow trench isolation region). The peripheral gate electrode 38 may be disposed to cross the peripheral active region 8. The peripheral interconnection lines 98 may extend in a line shape to overlap portions of the peripheral active region 8.

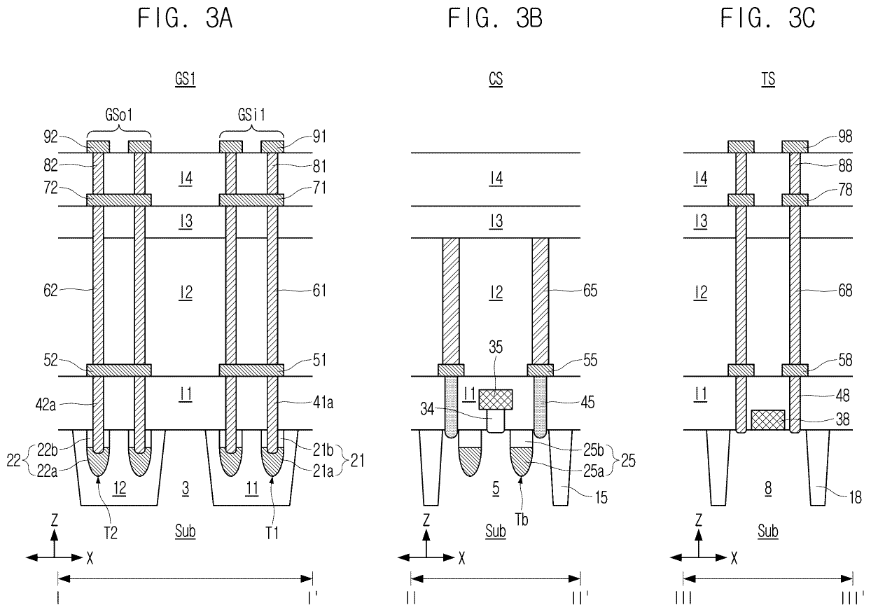

FIGS. 3A to 3C are longitudinal cross-sectional views schematically illustrating a guard ring structure GS1, a cell structure CS, and a peripheral transistor structure TS of a semiconductor device according to an embodiment of the present disclosure. FIG. 3A is a longitudinal sectional view taken along the line I-I′ of FIG. 2A, FIG. 3B is a longitudinal sectional view taken along the line II-II′ of FIG. 2B, and FIG. 3C is a longitudinal sectional view taken along the line III-III′ of FIG. 2C.

Referring to FIG. 3A, the guard ring structure GS1 of the semiconductor device may include an inner guard ring structure GSi1 and an outer guard ring structure GSo1. In a vertical direction Z, the inner guard ring structure GSi1 may include inner guard ring buried interconnection lines 21 in a substrate Sub, inner guard ring lower plugs 41a (note that two adjacent inner guard ring lower plugs 41a are depicted in FIG. 3A), an inner guard ring lower pad 51, inner guard ring middle plugs 61, an inner guard ring upper pad 71, inner guard ring upper plugs 81, and inner guard ring top pads 91 over the substrate Sub. The outer guard ring structure GSo1 may include outer guard ring buried interconnection lines 22 in the substrate Sub, outer guard ring lower plugs 42a (note that two adjacent outer guard ring lower plugs 42a are depicted in FIG. 3A), an outer guard ring lower pad 52, outer guard ring middle plugs 62, outer guard ring upper pad 72, outer guard ring upper plugs 82, and outer guard ring top pads 92 on the substrate Sub. The vertical direction Z may be perpendicular to each (and both) of the first horizontal direction X and the second horizontal direction Y.

The semiconductor device may further include an inner guard ring isolation region 11 (e.g., an inner guard ring shallow trench isolation region) and an outer guard ring isolation region 12 (e.g., an outer guard ring shallow trench isolation region) disposed in the substrate Sub. The inner guard ring isolation region 11 may surround side surfaces and lower portions of the inner guard ring buried interconnection lines 21. The outer guard ring isolation region 12 may surround side surfaces and lower portions of the outer guard ring buried interconnection lines 22. In another embodiment, the inner guard ring isolation region 11 and the outer guard ring isolation region 12 may be integrated into one without being separated.

The semiconductor device may include a lower interlayer insulating layer I1, a middle-lower interlayer insulating layer I2, a middle-upper interlayer insulating layer I3, and an upper interlayer insulating layer I4. The lower interlayer insulating layer I1 may be disposed on the substrate Sub to surround side surfaces of the inner and outer guard ring lower plugs 41a and 42a. The middle-lower interlayer insulating layer I2 and the middle-upper interlayer insulating layer I3 may be disposed on the lower interlayer insulating layer I1 to surround side surfaces of the inner and outer guard ring middle plugs 61 and 62. The upper interlayer insulating layer I4 may be disposed on the middle-upper interlayer insulating layer I3 to surround side surfaces of the inner and outer guard ring upper plugs 81 and 82. The middle-lower interlayer insulating layer I2 may surround sidewalls of lower portions of the inner and outer guard ring middle plugs 61 and 62. The middle-upper interlayer insulating layer I3 may be disposed on the middle-lower interlayer insulating layer I2 to surround sidewalls of upper portions of the inner and outer guard ring middle plugs 61 and 62. Each of the lower interlayer insulating layer I1, the middle-lower interlayer insulating layer I2, the middle-upper interlayer insulating layer I3, and the upper interlayer insulating layer I4 may include a silicon oxide-based insulating layer. In an embodiment, at least one of the lower interlayer insulating layer I1, the middle-lower interlayer insulating layer I2, the middle-upper interlayer insulating layer I3, and the upper interlayer insulating layer I4 may include a silicon nitride-based insulating layer.

The inner and outer guard ring buried interconnection lines 21 and 22 may be buried in inner and outer guard ring trenches T1 and T2 in the substrate Sub, respectively. The inner guard ring buried interconnection lines 21 and the outer guard ring buried interconnection lines 22 may be disposed at the same level parallel to each other in the first horizontal direction X. The inner guard ring buried interconnection lines 21 may include inner guard ring buried electrodes 21a and inner guard ring buried capping layers 21b, respectively. The outer guard ring buried interconnection lines 22 may include outer guard ring buried electrodes 22a and outer guard ring buried capping layers 22b, respectively. The inner and outer guard ring buried electrodes 21a and 22a may include a conductor such as a metal. The inner and outer guard ring buried capping layers 21b and 22b may include a silicon nitride-based insulating layer.

The inner and outer guard ring lower plugs 41a and 42a may vertically pass through the lower interlayer insulating layer I1 to be electrically connected to the inner and outer guard ring buried interconnection lines 21 and 22, respectively. The inner guard ring lower plugs 41a and the outer guard ring lower plugs 42a may be disposed at the same level adjacent to each other in the first horizontal direction X. The inner and outer guard ring lower plugs 41a and 42a may vertically pass through the inner and outer guard ring buried capping layers 21b and 22b to be electrically connected to the inner and outer guard ring buried electrodes 21a and 22a, respectively.

The inner and outer guard ring lower pads 51 and 52 may be disposed on the inner and outer guard ring lower plugs 41a and 42a and the lower interlayer insulating layer I1 to be connected to the inner and outer guard ring lower plugs 41a and 42a, respectively. The inner guard ring lower pad 51 and the outer guard ring lower pad 52 may be disposed at the same level adjacent to each other in the first horizontal direction X. The inner guard ring lower pad 51 may electrically connect the inner guard ring lower plugs 41a to each other in the first horizontal direction X. The outer guard ring lower pad 52 may electrically connect the outer guard ring lower plugs 42a to each other in the first horizontal direction X. Each of the inner and outer guard ring lower pads 51 and 52 may have a segment shape elongated in the first horizontal direction X in a longitudinal cross-sectional view. Side surfaces and top surfaces of the inner and outer guard ring lower pads 51 and 52 may be surrounded or covered by the middle-lower interlayer insulating layer I2.

The inner and outer guard ring middle plugs 61 and 62 may vertically pass through the middle-upper interlayer insulating layer I3 and the middle-lower interlayer insulating layer I2 to be electrically connected to the inner and outer guard ring lower pads 51 and 52, respectively. The inner guard ring middle plugs 61 and the outer guard ring middle plugs 62 may be disposed at the same level adjacent to each other in the first horizontal direction X. The inner guard ring lower pad 51 may electrically connect the inner guard ring middle plugs 61 to each other in the first horizontal direction X, and the outer guard ring lower pad 52 may electrically connect the outer guard ring middle plugs 62 to each other in the first horizontal direction X.

The inner and outer guard ring upper pads 71 and 72 may be disposed on the inner and outer guard ring middle plugs 61 and 62 and the middle-upper interlayer insulating layer I3 to be connected to the inner and outer guard ring middle plugs 61 and 62, respectively. The inner guard ring upper pad 71 and the outer guard ring upper pad 72 may be disposed at the same level adjacent to each other in the first horizontal direction X. The inner guard ring upper pad 71 may electrically connect the inner guard ring middle plugs 61 to each other in the first horizontal direction X. The outer guard ring upper pad 72 may electrically connect the outer guard ring middle plugs 62 to each other in the first horizontal direction X. Each of the inner and outer guard ring upper pads 71 and 72 may have a segment shape elongated in the first horizontal direction X in the longitudinal cross-sectional view. Side surfaces and top surfaces of the inner and outer guard ring upper pads 71 and 72 may be surrounded or covered by the upper interlayer insulating layer I4.

The inner and outer guard ring upper plugs 81 and 82 may vertically pass through the upper interlayer insulating layer I4 to be electrically connected to the inner and outer guard ring upper pads 71 and 72, respectively. The inner guard ring upper plugs 81 and the outer guard ring upper plugs 82 may be disposed at the same level adjacent to each other in the first horizontal direction X. The inner guard ring upper pad 71 may electrically connect the inner guard ring upper plugs 81 to each other in the first horizontal direction X, and the outer guard ring upper pad 72 may electrically connect the outer guard ring upper plugs 82 to each other in the first horizontal direction X.

The inner and outer guard ring top pads 91 and 92 may be disposed on the inner and outer guard ring upper plugs 81 and 82 and the upper interlayer insulating layer I4 to be connected to the inner and outer guard ring upper plugs 81 and 82, respectively. The inner guard ring top pads 91 and the outer guard ring top pads 92 may be disposed at the same level adjacent to each other in the first horizontal direction X. The inner guard ring top pads 91 may not electrically connect the inner guard ring upper plugs 81 to each other in the first horizontal direction X. The outer guard ring top pad 92 may not electrically connect the outer guard ring upper plugs 82 to each other in the first horizontal direction X.

The inner and outer guard ring buried electrodes 21a and 22a, the inner and outer guard ring lower plugs 41a and 42a, the inner and outer guard ring lower pads 51 and 52, the inner and outer guard ring middle plugs 61 and 62, the inner and outer guard ring upper pads 71 and 72, the inner and outer guard ring upper plugs 81 and 82, and the inner and outer guard ring top pads 91 and 92 may include the same material, for example, a metal such as tungsten. Accordingly, mutual adhesion between the inner and outer guard ring buried electrodes 21a and 22a, the inner and outer guard ring lower plugs 41a and 42a, the inner and outer guard ring lower pads 51 and 52, the inner and outer guard ring middle plugs 61 and 62, the inner and outer guard ring upper pads 71 and 72, the inner and outer guard ring upper plugs 81 and 82, and the inner and outer guard ring top pads 91 and 92 may be strengthened.

Physical resistance of the guard ring structure GS1 can be increased to improve protection from destruction, disconnection, separation, and lifting by stress from wafer grinding processes, dicing processes, sawing processes, and bonding processes, and elements of the guard ring structure GS1 may be physically, structurally, and electrically stabilized. The stable guard ring structure GS1 designed to prevent or substantially minimize destruction, disconnection, separation, and lifting can provide physical enforcement and prevent moisture from penetrating from the outside.

Referring to FIG. 3B, the cell structure CS of the semiconductor device may include a cell isolation region 15 and buried gate lines 25 in the substrate Sub, and a bit line contact plug 34, a bit line 35, a storage contact plug 45, a storage contact pad 55, and a storage electrode 65 on the substrate Sub. The cell isolation region 15 may define a cell active region 5. The cell isolation region 15 may include an insulating material. Each of the buried gate lines 25 may include a buried gate electrode 25a and a buried gate capping layer 25b disposed in a buried gate trench Tb. Each of the buried gate electrodes 25a may include the same material as the inner and outer guard ring buried electrodes 21a and 22a. The buried gate capping layers 25b may include the same material as the inner and outer guard ring buried capping layers 21b and 22b. The buried gate lines 25 and the inner and outer guard ring buried interconnection lines 21 and 22 may have the same structure and may be disposed at the same level to include the same material.

The bit line contact plug 34 may have a pillar shape electrically connected to a central portion of the cell active region 5. The bit line contact plug 34 may include at least one of a doped silicon, a metal silicide, a metal nitride, a metal, or a metal alloy.

The bit line 35 may be electrically connected to the bit line contact plug 34 and extend in a horizontal direction. The bit line 35 may include a lower insulating layer, a middle conductive electrode, and an upper insulating capping layer. The lower insulating layer of the bit line 35 may be formed not to cover an upper surface of the bit line contact plug 34. In another embodiment, the lower insulating layer of the bit line 35 may be omitted. For example, the middle conductive electrode of the bit line 35 may be directly connected to the upper surface of the bit line contact plug 34. The bit line contact plug 34 may pass through the lower insulating layer to be electrically connected to the middle conductive electrode.

The storage contact plugs 45 may have a pillar shape that vertically passes through the lower interlayer insulating layer I1 and is electrically connected to portions of both sides of the cell active region 5. The storage contact plugs 45 may include at least one of a doped silicon, a metal silicide, a metal nitride, a metal, or a metal alloy.

The storage contact pads 55 may be disposed between the storage contact plugs 45 and the storage electrodes 65 on the lower interlayer insulating layer I1 to electrically connect the storage contact plugs 45 to the storage electrodes 65. The storage contact pads 55 may include at least one of a doped silicon, a metal silicide, a metal nitride, a metal, or a metal alloy.

The storage electrodes 65 may vertically pass through the middle-lower interlayer insulating layer I2 and may be disposed on the storage contact pads 55. The storage electrodes 65 may include at least one of a doped silicon, a metal silicide, a metal nitride, a metal, or a metal alloy.

The lower interlayer insulating layer I1 may surround side surfaces of the bit line contact plug 34, the bit line 35, and the storage contact plugs 45. The lower interlayer insulating layer I1 may surround a portion of the lower surface, side surfaces, and an upper surface of the bit line 35. The middle-lower interlayer insulating layer I2 may surround side surfaces of the storage contact pads 55 and the storage electrodes 65. The middle-lower interlayer insulating layer I2 may cover portions of upper surfaces of the storage contact pads 55. The middle-upper interlayer insulating layer I3 may be disposed on upper surfaces of the storage electrodes 65. That is, the middle-upper interlayer insulating layer I3 may not surround side surfaces of the storage electrodes 65.

Referring to FIG. 3C, the peripheral transistor structure TS of the semiconductor device may include a peripheral isolation region 18 in the substrate Sub, a peripheral gate electrode 38, peripheral lower contact plugs 48, peripheral lower contact pads 58, peripheral middle contact plugs 68, peripheral upper contact pads 78, peripheral upper contact plugs 88, and peripheral interconnection lines 98 on the substrate Sub.

The peripheral isolation region 18 may define a peripheral active region 8. The peripheral isolation region 18 may include an insulating material. The peripheral gate electrode 38 may include a conductor. The peripheral gate electrode 38 may have the same structure as the bit line 35 of the cell structure CS. For example, the peripheral gate electrode 38 may include a gate dielectric layer at a lower portion, a conductive electrode layer at a middle portion, and an insulating capping layer at an upper portion.

The peripheral lower contact plugs 48 may vertically pass through the lower interlayer insulating layer I1 to be connected to the peripheral active region 8. The peripheral lower contact plugs 48 may be disposed adjacent to both sides of the peripheral gate electrode 38. The peripheral lower contact plugs 48 and the inner and outer guard ring lower plugs 41a and 42a may include the same material and may be disposed at the same level.

The peripheral lower contact pads 58 may be disposed between the peripheral lower contact plugs 48 and the peripheral middle contact plugs 68 on the lower interlayer insulating layer I1 to electrically connect the peripheral lower contact plugs 48 to the peripheral middle contact plugs 68. The peripheral lower contact pads 58 and the inner and outer guard ring lower pads 51 and 52 may include the same material and may be disposed at the same level.

The peripheral middle contact plugs 68 may be disposed to vertically pass through the middle-upper interlayer insulating layer I3 and the middle-lower interlayer insulating layer I2 to be connected to the peripheral lower contact pads 58. The peripheral middle contact plugs 68 and the inner and outer guard ring middle plugs 61 and 62 may include the same material and may be disposed at the same level.

The peripheral upper contact pads 78 may be disposed between the peripheral middle contact plugs 68 and the peripheral upper contact plugs 88 on the middle-upper interlayer insulating layer I3 to electrically connect the peripheral middle contact plugs 68 to the peripheral upper contact plugs 88. The peripheral upper contact pads 78 and the inner and outer guard ring upper pads 71 and 72 may include the same material and may be disposed at the same level.

The peripheral upper contact plugs 88 may vertically pass through the upper interlayer insulating layer I4 to be electrically connected to the peripheral upper contact pads 78. The peripheral upper contact plugs 88 and the inner and outer guard ring upper plugs 81 and 82 may include the same material and may be disposed at the same level.

The peripheral interconnection lines 98 may be disposed on the upper interlayer insulating layer I4 and the peripheral upper contact plugs 88 to horizontally extend (for example across the upper surface of the upper interlayer insulating layer I4 and the peripheral upper contact plugs 88). The peripheral interconnection lines 98 and the inner and outer guard ring top pads 91 and 92 may include the same material and may be disposed at the same level.

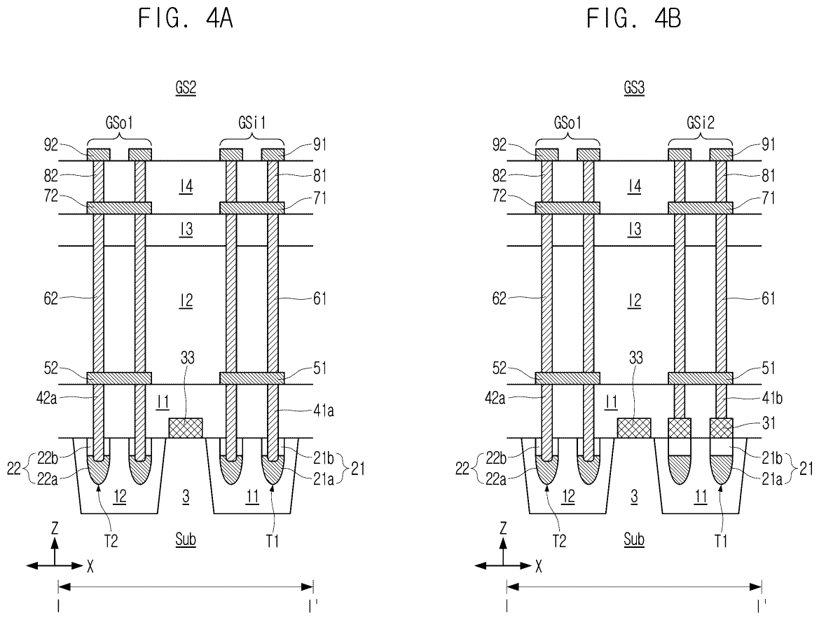

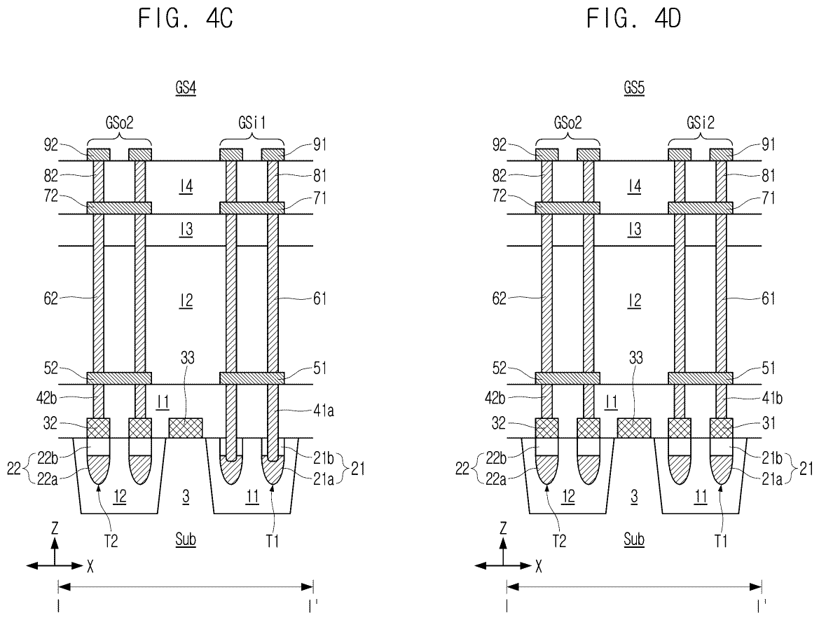

FIGS. 4A to 4D are longitudinal cross-sectional views schematically illustrating guard ring structures GS2 to GS5 of semiconductor devices according to other embodiments of the present disclosure. FIGS. 4A to 4D are longitudinal cross-sectional views taken along the line I-I′ of FIG. 2A. Referring to FIG. 4A, the guard ring structure GS2 of the semiconductor device may include an inner guard ring structure GSi1, an outer guard ring structure GSo1, and a guard ring dummy gate electrode 33. Compared with the guard ring structure GS1 of FIG. 3A, the guard ring structure GS2 may further include the guard ring dummy gate electrode 33. The guard ring dummy gate electrode 33 may be disposed on the substrate Sub between the inner guard ring structure GSi1 and the outer guard ring structure GSo1. The guard ring dummy gate electrode 33 may have the same structure as the peripheral gate electrode 38, may include the same material, and may be disposed at the same level. The guard ring dummy gate electrode 33 may have a short segment shape or a long line shape extending in the second horizontal direction Y. The guard ring dummy gate electrode 33 may be electrically floated.

Referring to FIG. 4B, the guard ring structure GS3 of the semiconductor device may include an inner guard ring structure GSi2, an outer guard ring structure GSo1, and a guard ring dummy gate electrode 33. In another embodiment, the guard ring dummy gate electrode 33 may be omitted. The inner guard ring structure GSi2 may further include inner guard ring support electrodes 31 disposed on the inner guard ring buried interconnection lines 21. The inner guard ring support electrodes 31 may be disposed between the inner guard ring buried interconnection lines 21 and an inner guard ring lower plugs 41b. The inner guard ring support electrodes 31 may have the same structure as the peripheral gate electrode 38, may include the same material, and may be disposed at the same level. For example, the inner guard ring support electrodes 31 may include a dielectric layer at a lower portion, a conductive electrode layer at a middle portion, and an insulating capping layer at au upper portion, respectively. The inner guard ring lower plugs 41b may be electrically connected to the inner guard ring support electrodes 31. The inner guard ring buried electrodes 21a and the inner guard ring support electrodes 31 may not be physically, electrically, or directly connected.

Referring to FIG. 4C, the guard ring structure GS4 of the semiconductor device may include an inner guard ring structure GSi1, an outer guard ring structure GSo2, and a guard ring dummy gate electrode 33. In another embodiment, the guard ring dummy gate electrode 33 may be omitted. The outer guard ring structure GSo2 may further include outer guard ring support electrodes 32 disposed on the outer guard ring buried interconnection lines 22. The outer guard ring support electrodes 32 may be disposed between the outer guard ring buried interconnection lines 22 and the outer guard ring lower plugs 42b. The outer guard ring support electrodes 32 may have the same structure as the peripheral gate electrode 38, may include the same material, and may be disposed at the same level. For example, the outer guard ring support electrodes 32 may include a dielectric layer at a lower portion, a conductive electrode layer at a middle portion, and an insulating capping layer at an upper portion, respectively. The outer guard ring lower plugs 42b may be electrically connected to the outer guard ring support electrodes 32. The outer guard ring buried electrodes 22a and the outer guard ring support electrodes 32 may not be physically, electrically, or directly connected.

Referring to FIG. 4D, the guard ring structure GS5 of the semiconductor device may include an inner guard ring structure GSi2, an outer guard ring structure GSo2, and a guard ring dummy gate electrode 33. In another embodiment, the guard ring dummy gate electrode 33 may be omitted. The inner guard ring structure GSi2 can be understood with reference to FIG. 4B, and the outer guard ring structure GSo2 can be understood with reference to FIG. 4C.

FIGS. 5A and 5B are longitudinal cross-sectional views taken along the line IV-IV′ or V-V′ of FIG. 2A to describe the inner or outer guard ring structures GSi1, GSi2, GSo1, and GSo2 according to an embodiment of the present disclosure. Referring to FIG. 5A, the inner or outer guard ring structures GSi1 and GSo1 may include inner or outer guard ring buried interconnection lines 21 or 22 in the substrate Sub, inner or outer guard ring lower plugs 41a or 42a in the substrate Sub, inner or outer guard ring lower pads 51 or 52, inner or outer guard ring middle plugs 61 or 62, inner or outer guard ring upper pads 71 or 72, inner or outer guard ring upper plugs 81 or 82, and inner or outer guard ring top pads 91 or 92. The semiconductor device may further include inner or outer guard ring STI regions 11 or 12 formed in the substrate Sub.

Each of the inner or outer guard ring lower plugs 41a or 42a, the inner or outer guard ring middle plugs 61 or 62, and the inner or outer guard ring upper plugs 81 or 82 may have a wall shape. The inner or outer guard ring lower plugs 41a or 42a, the inner or outer guard ring middle plugs 61 or 62, and the inner or outer guard ring upper plugs 81 or 82 may have a wall shape to extend in the second horizontal direction Y.

Each of the inner or outer guard ring buried interconnection lines 21 or 22, and the inner or outer guard ring top pads 91 or 92 may have a line shape extending in the second horizontal direction Y. The inner or outer guard ring isolation regions 11 or 12 may extend to surround the inner or outer guard ring buried interconnection lines 21 or 22 in the second horizontal direction Y.

Referring to FIG. 5B, the inner or outer guard ring structures GSi2 or GSo2 may include inner or outer guard ring buried interconnection lines 21 or 22 in the substrate Sub, inner or outer guard ring support electrodes 31 or 32, inner or outer guard ring lower plugs 41b or 42b, inner or outer guard ring lower pads 51 or 52, inner or outer guard ring middle plugs 61 or 62, inner or outer guard ring upper pads 71 or 72, inner or outer guard ring upper plugs 81 or 82, and inner or outer guard ring top pads 91 or 92. The semiconductor device may further include inner or outer guard ring isolation regions 11 or 12 formed in the substrate Sub.

The inner or outer guard ring structures GSi1, GSi2, GSo1, or GSo2 illustrated in FIGS. 5A and 5B may be combined with each other. For example, the inner or outer guard ring buried interconnection lines 21 or 22 and the inner or outer guard ring support electrodes 31 or 32 may be selectively combined and arranged. That is, some of the inner or outer guard ring lower plugs 41a, 41b, 42a, or 42b may be electrically connected to each other by the inner or outer guard ring buried interconnection lines 21 or 22, and others of the inner or outer guard ring lower plugs 41a, 41b, 42a, or 42b may be electrically connected to each other by the inner or outer guard ring support electrodes 31 or 32.

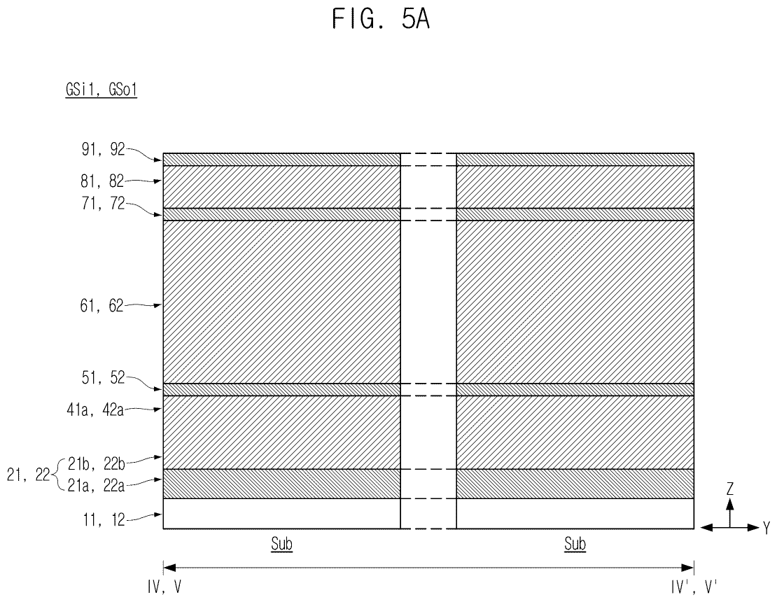

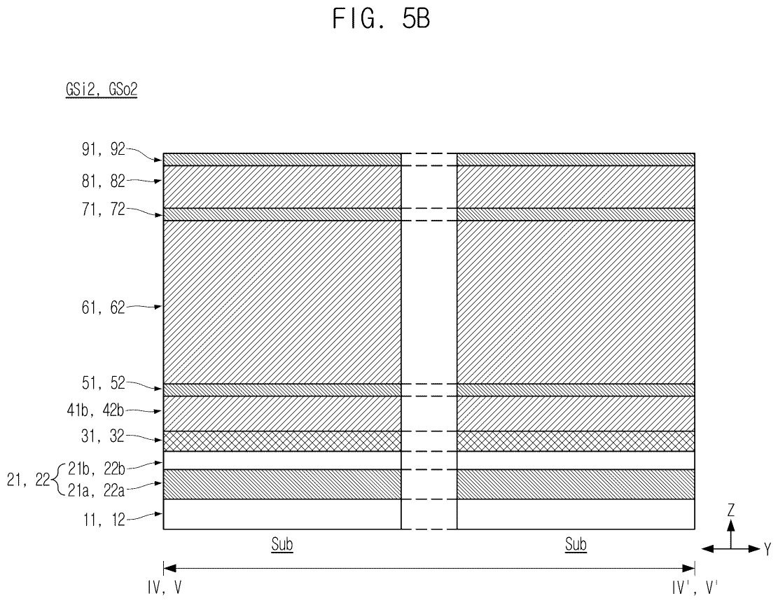

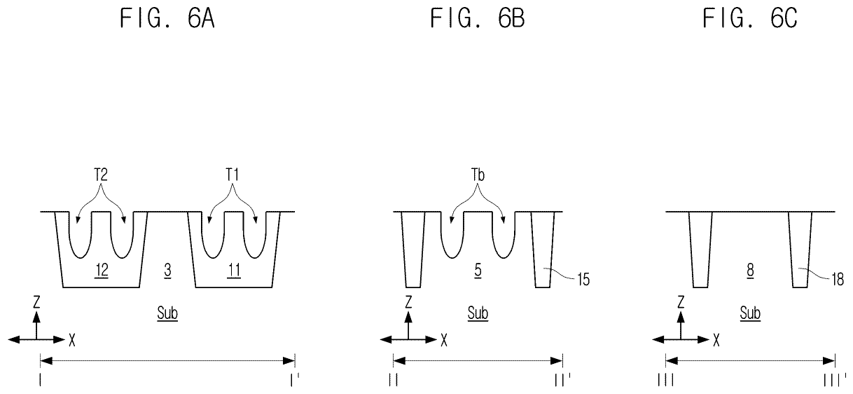

FIGS. 6A to 6C to 13A to 13C are longitudinal cross-sectional views illustrating a method of manufacturing a semiconductor device according to an embodiment of the present disclosure, with each of the letters A, B, and C representing different longitudinal cross-sectional views while each of the numbers 6 to 13 represent different stages of the process. FIGS. 6A to 13A are longitudinal cross-sectional views taken along the line I-I′ of FIG. 2A, FIGS. 6B to 13B are longitudinal cross-sectional views taken along the line II-II′ of FIG. 2B, and FIGS. 6C to 13C are longitudinal cross-sectional views taken along the line III-III′ of FIG. 2C.

Referring to FIGS. 6A to 6C, the method may include simultaneously forming an inner guard ring isolation region 11, an outer guard ring isolation region 12, a cell isolation region 15, and a peripheral isolation region 18 in a substrate Sub. The inner and outer guard ring isolation regions 11 and 12 may be formed in the substrate Sub of the guard ring area GR of FIG. 1B. The inner and outer guard ring isolation regions 11 and 12 may define a guard ring active region 3. The cell isolation region 15 may be formed in at least one of the cell areas C1 to C4 of FIG. 1B. The cell isolation region 15 may define a cell active region 15. The peripheral isolation region 18 may be formed in at least one of the peripheral circuit areas P1 to P9 of FIG. 1B. The peripheral isolation region 18 may define a peripheral active region 8. Forming the inner and outer guard ring isolation regions 11 and 12, the cell isolation region 15, and the peripheral isolation region 18 may include performing an isolation forming process. In another embodiment, the inner and outer guard ring isolation regions 11 and 12 may be integrated without being separated.

The method may further include simultaneously forming inner and outer guard ring trenches T1 and T2 in the inner and outer guard ring isolation regions 11 and 12, and forming buried gate trenches Tb in the cell active region 5 by performing a photolithography process and an etching process, respectively.

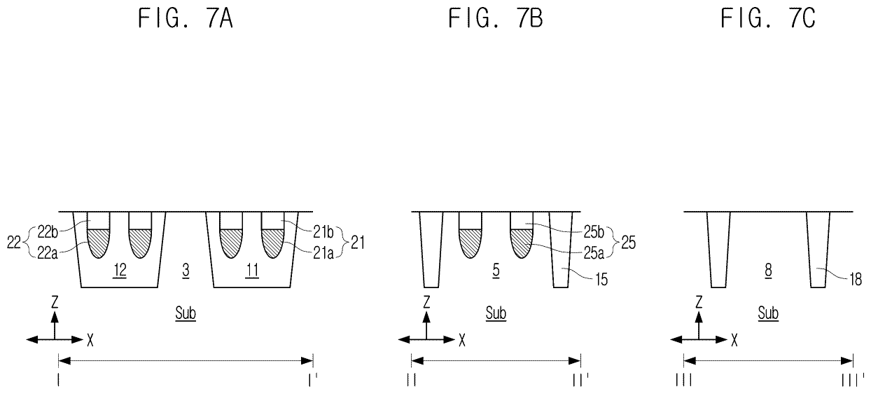

Referring to FIGS. 7A to 7C, the method may further include simultaneously forming inner and outer guard ring buried interconnection lines 21 and 22 in the inner and outer guard ring trenches T1 and T2, and forming buried gate lines 25 in the buried gate trenches Tb by performing a filling process. The filling process may include a surface oxidation process, a deposition process, and a planarization process.

Forming the inner guard ring buried interconnection lines 21 may include forming inner guard ring buried electrodes 21a in lower portions of the inner guard ring trenches T1 and forming inner guard ring buried capping layers 21b in upper portions of the inner guard ring trenches T1.

Forming the outer guard ring buried interconnection lines 22 may include forming outer guard ring buried electrodes 22a in lower portions of the outer guard ring trenches T2, and forming outer guard ring buried capping layers 22b in upper portions of the outer guard ring trenches T2.

Forming the buried gate lines 25 may include forming buried gate electrodes 25a in lower portions of the buried gate trenches Tb, and forming buried gate capping layers 25b in upper portions of the buried gate trenches Tb.

The inner guard ring buried electrodes 21a, the outer guard ring buried electrodes 22a, and the buried gate electrodes 25a may include a conductor such as a metal. The inner guard ring buried electrodes 21a, the outer guard ring buried electrodes 22a, and the buried gate electrodes 25a may include the same material and may be formed simultaneously.

The inner guard ring buried capping layers 21b, the outer guard ring buried capping layers 22b, and the buried gate capping layers 25b may include an insulating material such as silicon nitride. The inner guard ring buried capping layers 21b, the outer guard ring buried capping layers 22b, and the buried gate capping layers 25b may include the same material and may be formed simultaneously.

Therefore, the inner guard ring buried interconnection lines 21, the outer guard ring buried interconnection lines 22, and the buried gate lines 25 may be simultaneously formed in the same structure.

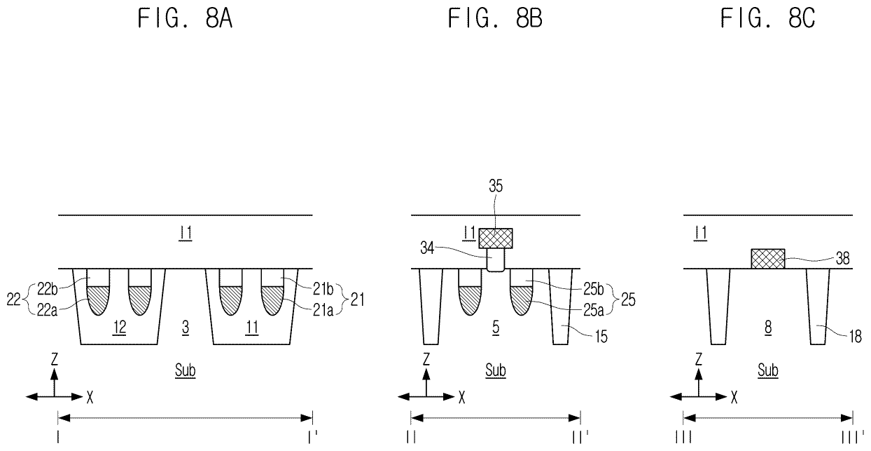

Referring to FIGS. 8A to 8C, the method may further include forming a bit line contact plug 34 on the cell active region 5 between the buried gate lines 25. Forming the bit line contact plug 34 may include forming a pillar-shaped conductor of at least one of a doped silicon, a metal silicide, a metal nitride, a metal, or a metal alloy by performing a deposition process, a photolithography process, an etching process, and a planarization process.

The method may further include simultaneously forming a bit line 35 on the bit line contact plug 34, and a peripheral gate electrode 38 on the peripheral active region 8, respectively. Formation of the bit line 35 and the peripheral gate electrode 38 may include forming a lower insulating layer, forming a middle conductive electrode, and forming an upper insulating capping layer. In another embodiment, the forming of the lower insulating layer of the bit line 35 may be omitted. The lower insulating layer may include a silicon oxide-based insulating layer, the middle conductive electrode may include a metal, and the upper insulating capping layer may include a silicon nitride-based insulating layer.

The method may further include forming a lower interlayer insulating layer I1. The upper surface of the lower interlayer insulating layer I1 may be flat.

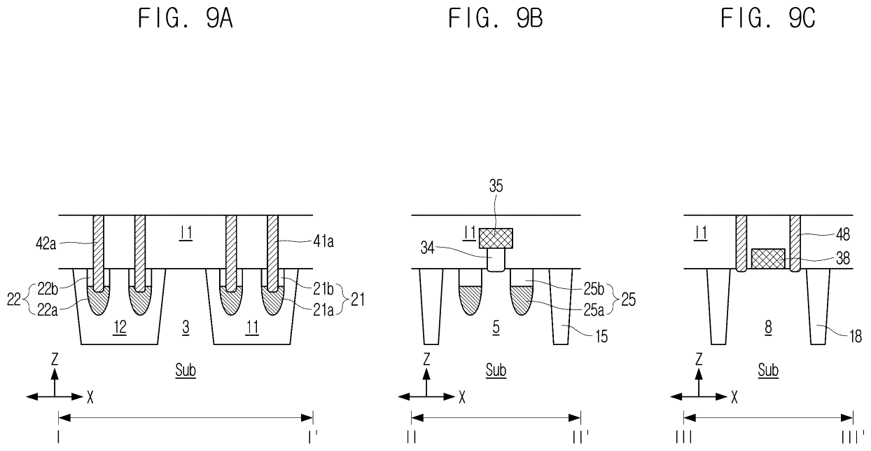

Referring to FIGS. 9A to 9C, the method may further include simultaneously forming inner guard ring lower plugs 41a, outer guard ring lower plugs 42a, and peripheral lower contact plugs 48. Forming the inner guard ring lower plugs 41a may include forming holes or trenches vertically penetrating the lower interlayer insulating layer I1 and the inner guard ring buried capping layers 21b to expose the inner guard ring buried electrodes 21a, and filling the holes or trenches with a conductor. Forming the outer guard ring lower plugs 42a may include forming holes or trenches vertically penetrating the lower interlayer insulating layer I1 and the outer guard ring buried capping layers 22b to expose the outer guard ring buried electrodes 22a, and filling the holes or trenches with a conductor. Forming the peripheral lower contact plugs 48 may include forming holes vertically penetrating the lower interlayer insulating layer I1 to expose the peripheral active region 8, and filling the holes with a conductor. The inner guard ring lower plugs 41a, the outer guard ring lower plugs 42a, and the peripheral lower contact plugs 48 may include the same material. The inner guard ring buried electrodes 21a and the inner guard ring lower plugs 41a may include the same material. The outer guard ring buried electrodes 22a and the outer guard ring lower plugs 42a may include the same material. Accordingly, the inner guard ring buried electrodes 21a and the inner guard ring lower plugs 41a, the outer guard ring buried electrodes 22a and the outer guard ring lower plugs 42a can form strong and stable metal bonds.

Referring to FIGS. 10A to 10C, the method may further include forming storage contact plugs 45, and simultaneously forming inner and outer guard ring lower pads 51 and 52, storage contact pads 55, and peripheral lower contact pads 58.

Forming the storage contact plugs 45 may include vertically penetrating the lower interlayer insulating layer I1 to form holes exposing surfaces of the cell active region 5, and filling the holes with a conductor. The storage contact plugs 45 may include at least one of a doped silicon, a metal silicide, a metal nitride, a metal, or a metal alloy.

The inner and outer guard ring lower pads 51 and 52 may include the same material as the inner and outer guard ring lower plugs 41a and 42a. The peripheral lower contact pads 58 may include the same material as the peripheral lower contact plugs 48. The inner and outer guard ring lower pads 51 and 52, the storage contact pads 55, and the peripheral lower contact pads 58 may include the same material.

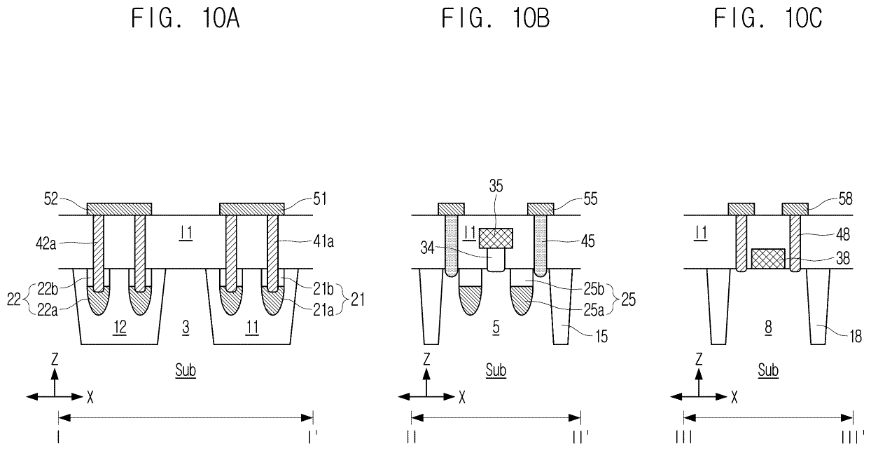

Referring to FIGS. 11A to 11C, the method may further include forming a middle-lower interlayer insulating layer I2, and forming the storage electrodes 65.

Forming the middle-lower interlayer insulating layer I2 may include forming a silicon oxide-based insulating layer on the lower interlayer insulating layer I1 by performing a deposition process. The middle-lower interlayer insulating layer I2 may cover the inner and outer guard ring lower pads 51 and 52, the storage contact pads 55, and the peripheral lower contact pads 58.

Forming the storage electrodes 65 may include vertically penetrating the middle-lower interlayer insulating layer I2 to form holes exposing the storage contact pads 55 and filling the holes with a conductor. The storage electrodes 65 may be formed from at least one of a doped silicon, a metal silicide, a metal nitride, a metal, or a metal alloy.

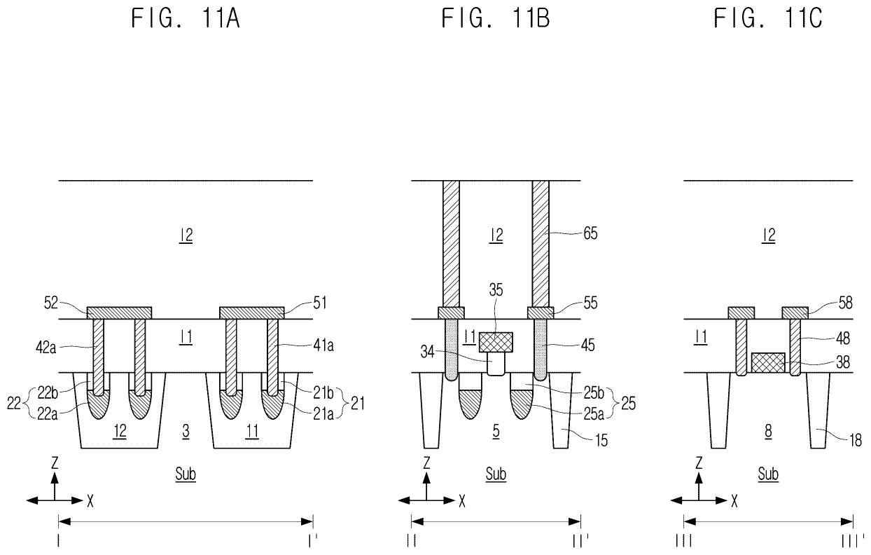

Referring to FIGS. 12A to 12C, the method may further include forming a middle-upper interlayer insulating layer I3 and simultaneously forming inner and outer guard ring middle plugs 61 and 62 and peripheral middle contact plugs 68. Forming the middle-upper interlayer insulating layer I3 may include forming the silicon oxide-based insulating layer on the middle-lower interlayer insulating layer I2 by performing a deposition process.

Forming the inner and outer guard ring middle plugs 61 and 62 and the peripheral middle contact plugs 68 may include vertically penetrating the middle-upper interlayer insulating layer I3 and the middle-lower interlayer insulating layer I2 to form trenches or holes exposing surfaces of the inner and outer guard ring lower pads 51 and 52 and the peripheral lower contact pads 58 and filling the trenches or holes with a conductor. The inner and outer guard ring middle plugs 61 and 62 and the peripheral middle contact plugs 68 may include the same material as the inner and outer guard ring lower pads 51 and 52 and the peripheral lower contact pads 58.

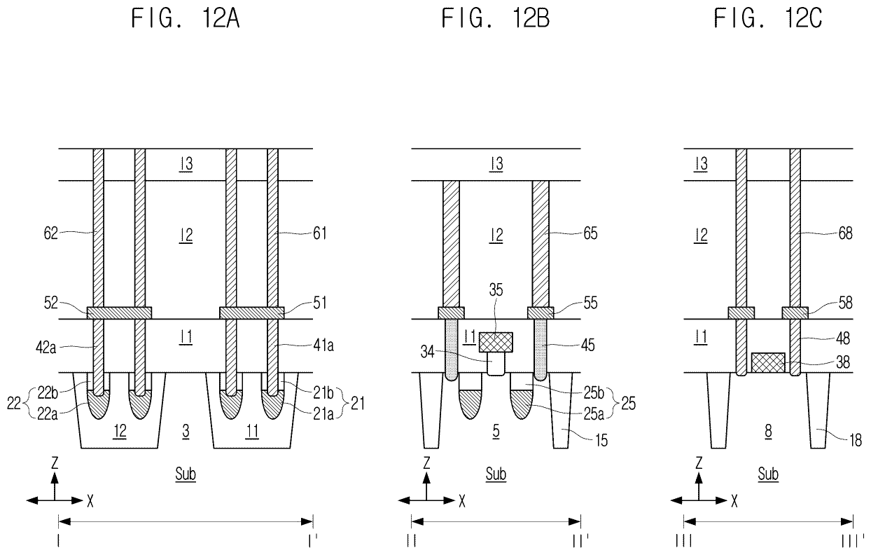

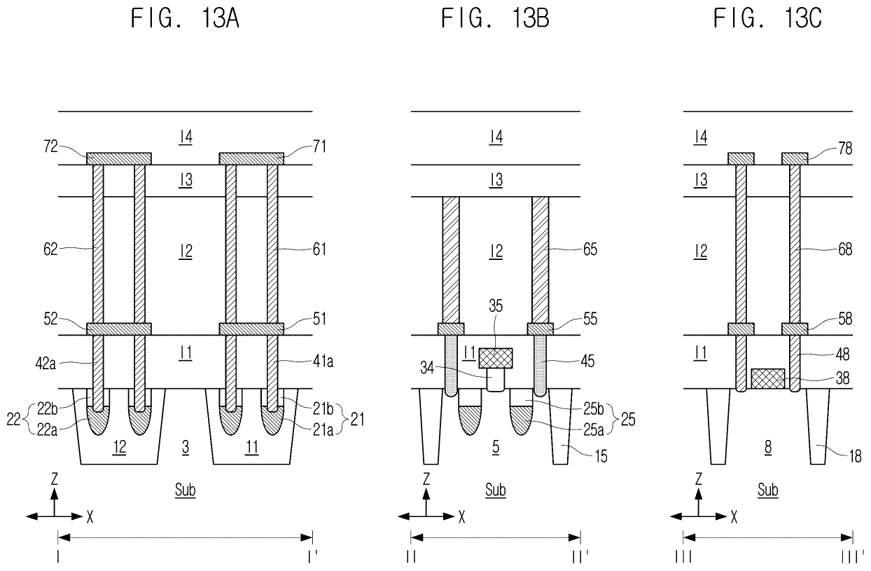

Referring to FIGS. 13A to 13C, the method may further include simultaneously forming inner and outer guard ring upper pads 71 and 72, and peripheral upper contact pads 78, and forming an upper interlayer insulating layer I4.

The inner and outer guard ring upper pads 71 and 72 may include the same material as the inner and outer guard ring middle plugs 61 and 62. The peripheral upper contact pads 78 may include the same material as the peripheral middle contact plugs 68. The inner and outer guard ring upper pads 71 and 72 and the peripheral upper contact pads 78 may include the same material.

Forming the upper interlayer insulating layer I4 may include forming a silicon oxide-based insulating layer on the middle-upper interlayer insulating layer I3 by performing a deposition process.

Thereafter, referring to FIGS. 3A to 3C, the method may further include simultaneously forming inner and outer guard ring upper plugs 81 and 82 and peripheral upper contact plugs 88, and simultaneously forming inner and outer guard ring top pads 91 and 92 and peripheral interconnection lines 98. Forming the inner and outer upper guard ring plugs 81 and 82 and the peripheral upper contact plugs 88 may include vertically penetrating the upper interlayer insulating layer I4 to form trenches or holes exposing top surfaces of the inner and outer guard ring upper pads 71 and 72 and the peripheral upper contact pads 78, and filling the trenches or holes with a conductor.

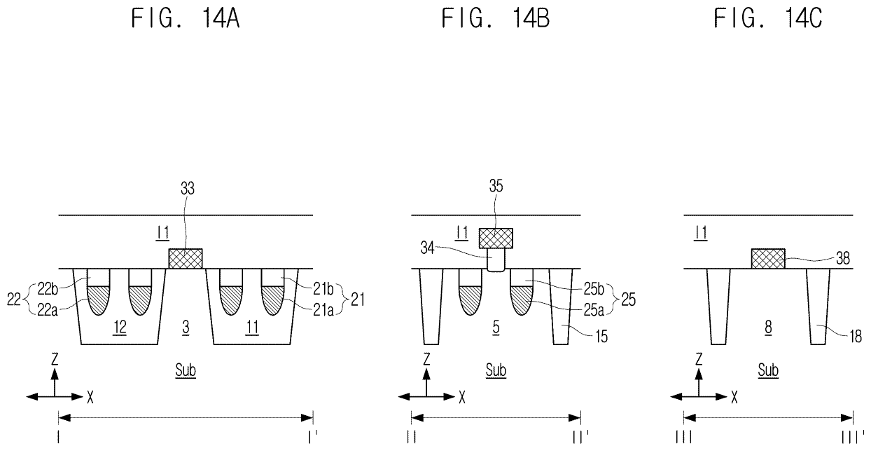

FIGS. 14A to 14C are longitudinal cross-sectional views illustrating a method of manufacturing a semiconductor device according to another embodiment of the present disclosure. FIG. 14A is a longitudinal sectional view taken along the line I-I′ of FIG. 2A, FIG. 14B is a longitudinal sectional view taken along the line II-II′ of FIG. 2B, and FIG. 14C is a longitudinal sectional view taken along the line III-III′ of FIG. 2C.

Referring to FIGS. 14A to 14C, the method may include performing the processes described with reference to FIGS. 6A to 6C and 7A to 7C, forming a bit line contact plug 34 on a cell active region 5 between buried gate lines 25, and simultaneously forming a guard ring dummy gate electrode 33, a bit line 35, and a peripheral gate electrode 38 on the guard ring active region 3, the bit line contact plug 34, and the peripheral active region 8, respectively. The guard ring dummy gate electrode 33 may be formed on the substrate Sub or the guard ring active region 3 between the inner guard ring isolation region 11 and the outer guard ring isolation region 12, or between the inner guard ring buried interconnection lines 21 and the outer guard ring buried interconnection lines 22.

The guard ring dummy gate electrode 33 may have the same structure as the peripheral gate electrode 38.

The guard ring dummy gate electrode 33 may be a resistance element to prevent dicing in subsequent planarization processes, e.g., a CMP process, to planarize an upper surface of the lower interlayer insulating layer I1.

Thereafter, the method may further include performing the processes described with reference to FIGS. 9A to 9C to 13A to 13C, simultaneously forming inner and outer guard ring upper plugs 81 and 82 and peripheral upper contact plugs 88 with reference to FIGS. 3A to 3C and/or 4A, and simultaneously forming inner and outer guard ring top pads 91 and 92 and peripheral interconnection lines 98.

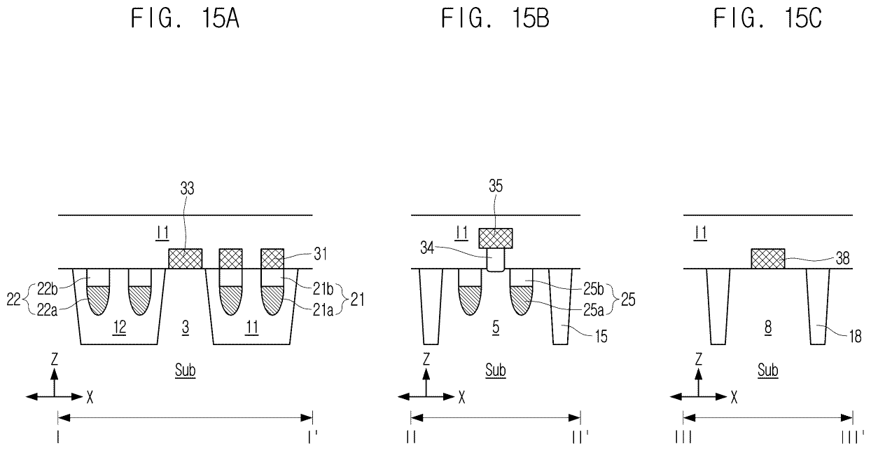

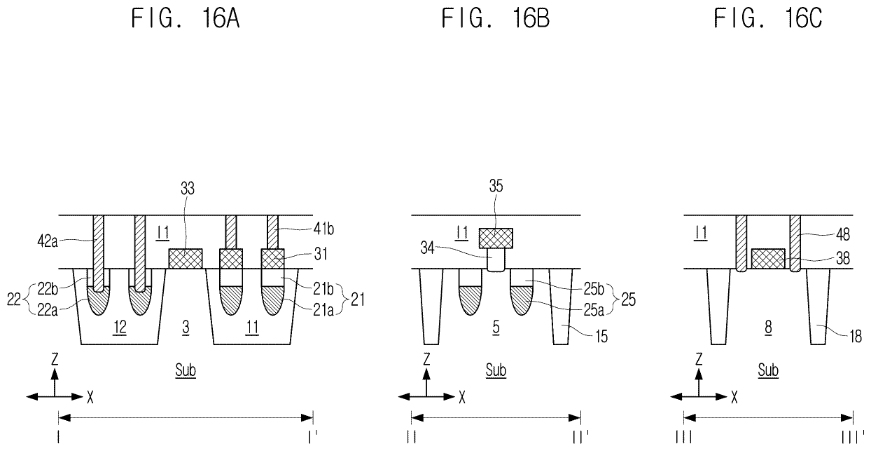

FIGS. 15A to 15C to 16A to 16C are longitudinal cross-sectional views illustrating a method of manufacturing a semiconductor device according to another embodiment of the present disclosure. FIGS. 15A and 16A are longitudinal cross-sectional views taken along the line I-I′ of FIG. 2A, FIGS. 15B and 16B are longitudinal cross-sectional views taken along the line II-II′ of FIG. 2B, and FIGS. 15C and 16C are longitudinal cross-sectional views taken along the line III-III′ of FIG. 2C.

Referring to FIGS. 15A to 15C, the method may include performing the processes described with reference to FIGS. 6A to 6C and 7A to 7C, forming a bit line contact plug 34 on a cell active region 5 between buried gate lines 25, simultaneously forming a guard ring dummy gate electrode 33, inner guard ring support electrodes 31, a bit line 35, and a peripheral gate electrode 38 on a guard ring active region 3, an inner guard ring isolation region 11, the bit line contact plug 34, and on the peripheral gate electrode 8, respectively. The guard ring dummy gate electrode 33 may be understood with reference to FIG. 14A.

The inner guard ring support electrodes 31 may be formed on the inner guard ring buried interconnection lines 21 to be vertically aligned with the inner guard ring buried interconnection lines 21.

The inner guard ring support electrodes 31 may have the same structure as the peripheral gate electrode 38.

The inner guard ring support electrodes 31 may be resistance elements to prevent dicing and moisture penetration in subsequent planarization processes.

In another embodiment, the guard ring dummy gate electrode 33 may be omitted.

Referring to FIGS. 16A to 16C, the method may further include simultaneously forming inner guard ring lower plugs 41b, outer guard ring lower plugs 42a, and peripheral lower contact plugs 48. The inner guard ring lower plugs 41b may be electrically connected to the inner guard ring support electrodes 31. The inner guard ring lower plugs 41b may not be physically or electrically connected to the inner guard ring buried electrodes 21a.

Thereafter, the method may further include performing the processes described with reference to FIGS. 10A to 10C to 13A to 13C, simultaneously forming inner and outer guard ring upper plugs 81 and 82 and peripheral upper contact plugs 88, and simultaneously forming inner and outer guard ring top pads 91 and 92 and peripheral interconnection lines 98 with reference to FIGS. 3A to 3C and/or FIG. 4B.

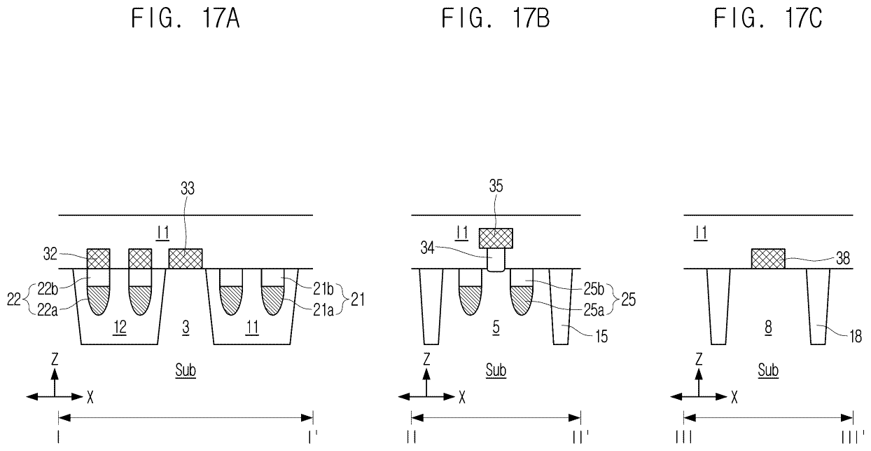

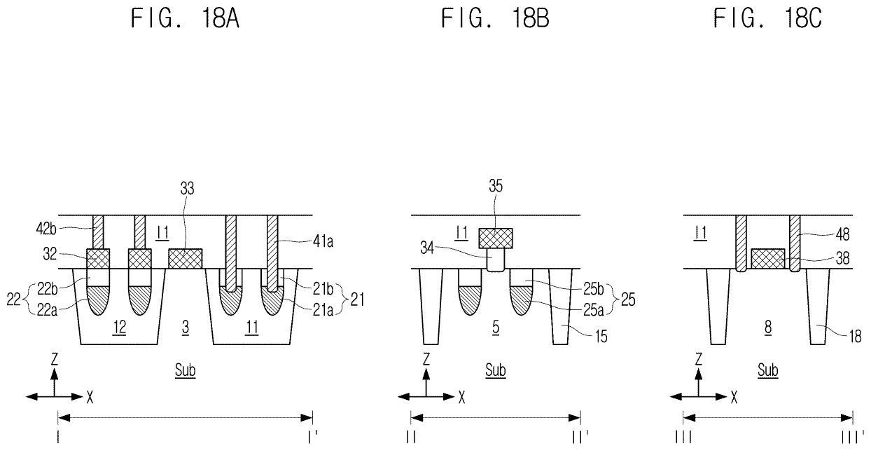

FIGS. 17A to 17C to 18A to 18C are longitudinal cross-sectional views illustrating a method of manufacturing a semiconductor device according to another embodiment of the present disclosure. FIGS. 17A and 18A are longitudinal cross-sectional views taken along the line I-I′ of FIG. 2A, FIGS. 17B and 18B are longitudinal cross-sectional views taken along the line II-II′ of FIG. 2B, and FIGS. 17C and 18C are longitudinal cross-sectional views taken along the line III-III′ of FIG. 2C.

Referring to FIGS. 17A to 17C, the method may include performing the processes described with reference to FIGS. 6A to 6C and 7A to 7C, forming a bit line contact plug 34 on a cell active region 5 between buried gate lines 25, simultaneously forming a guard ring dummy gate electrode 33, outer guard ring support electrodes 32, a bit line 35, and a peripheral gate electrode 38 on a guard ring active region 3, an outer guard ring isolation region 12, a bit line contact plug 34, and a peripheral active region 8, respectively. The guard ring dummy gate electrode 33 may be understood with reference to FIG. 14A.

The outer guard ring support electrodes 32 may be formed on the outer guard ring buried interconnection lines 22 to be vertically aligned with the outer guard ring buried interconnection lines 22.

The outer guard ring support electrodes 32 may have the same structure as the peripheral gate electrode 38.

The outer guard ring support electrodes 32 may be (form, include) resistance elements to prevent dicing and moisture penetration in subsequent planarization processes.

In another embodiment, the guard ring dummy gate electrode 33 may be omitted.

Referring to FIGS. 18A to 18C, the method may further include simultaneously forming inner guard ring lower plugs 41a, outer guard ring lower plugs 42b, and peripheral lower contact plugs 48. The outer guard ring lower plugs 42b may be electrically connected to the outer guard ring support electrodes 32. The outer guard ring lower plugs 42b may not be physically or electrically connected to the outer guard ring buried electrodes 22a.

Thereafter, the method may further include performing the processes described with reference to FIGS. 10A to 10C to 13A to 13C, simultaneously forming inner and outer guard ring upper plugs 81 and 82 and peripheral upper contact plugs 88, as described with reference to FIGS. 3A to 3C and/or 4C, and simultaneously forming inner and outer guard ring top pads 91 and 92 and peripheral interconnection lines 98.

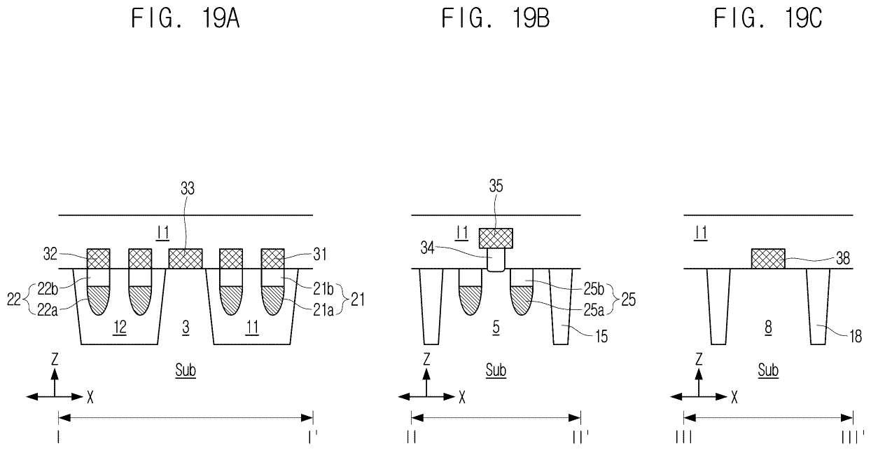

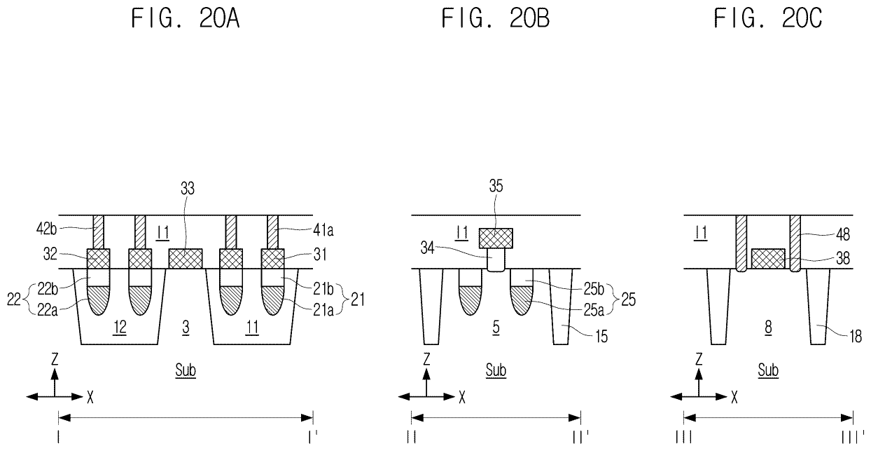

FIGS. 19A to 19C to 20A to 20C are longitudinal cross-sectional views illustrating a method of manufacturing a semiconductor device according to another embodiment of the present disclosure. FIGS. 19A and 20A are longitudinal cross-sectional views taken along the line I-I′ of FIG. 2A, FIGS. 19B and 20B are longitudinal cross-sectional views taken along the line II-II′ of FIG. 2B, and FIGS. 19C and 20C are longitudinal cross-sectional views taken along the line III-III′ of FIG. 2C.

Referring to FIGS. 19A to 19C, the method may include performing the processes described with reference to FIGS. 6A to 6C and 7A to 7C, forming a bit line contact plug 34 on a cell active region 5 between the buried gate lines 25, simultaneously forming a guard ring dummy gate electrode 33, inner and outer guard ring support electrodes 31 and 32, a bit line 35, and a peripheral gate electrode 38 on a guard ring active region 3, inner and outer guard ring isolation regions 11 and 12, the bit line contact plug 34, and a peripheral active region 8, respectively. The guard ring dummy gate electrode 33 may be understood with reference to FIG. 14A.

Referring to FIGS. 20A to 20C, the method may further include simultaneously forming inner and outer guard ring lower plugs 41b and 42b and peripheral lower contact plugs 48.

Thereafter, the method may further include performing the processes described with reference to FIGS. 10A to 10C to 13A to 13C, simultaneously forming inner and outer guard ring upper plugs 81 and 82 and peripheral upper contact plugs 88 with reference to FIGS. 3A to 3C and/or 4D, and simultaneously forming inner and outer guard ring top pads 91 and 92 and peripheral interconnection lines 98.

According to the embodiments of the present disclosure, the physical adhesion of the guard ring structure can be strengthened, and the semiconductor device can be protected from physical damage and moisture penetration.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

1. A semiconductor device comprising:
a cell structure disposed in a cell area, the cell structure including a buried gate line disposed in a substrate; and
a guard ring structure disposed in a guard ring area to surround the cell structure, wherein the buried gate line includes:
a buried gate electrode disposed in a lower portion of a buried gate trench disposed in the substrate; and
a buried gate capping layer disposed in an upper portion of the buried gate trench,
wherein the guard ring structure includes:
a guard ring buried interconnection line disposed in the substrate;
a guard ring lower plug disposed over the substrate and electrically connected to the guard ring buried interconnection line; and
a guard ring top pad disposed over the guard ring lower plug and electrically connected to the guard ring lower plug, and
wherein the guard ring buried interconnection line includes:
a guard ring buried electrode disposed in a lower portion of a guard ring trench disposed in the substrate; and
a guard ring buried capping layer disposed in an upper portion of the guard ring trench.

2. The semiconductor device of claim 1,
wherein the buried gate electrode and the guard ring buried electrode include a same material, and
wherein the buried gate capping layer and the guard ring buried capping layer include a same material.

3. The semiconductor device of claim 1,
wherein the guard ring lower plug vertically passes through the guard ring buried capping layer to connect to the guard ring buried electrode.

4. The semiconductor device of claim 1, wherein:
the guard ring buried interconnection line includes a plurality of inner guard ring buried interconnection lines;
the guard ring lower plug includes a plurality of inner guard ring lower plugs;
the guard ring top pad includes an inner guard ring top pad;
the guard ring structure includes an inner guard ring structure including the plurality of inner guard ring buried interconnection lines, the plurality of inner guard ring lower plugs, and the inner guard ring top pad;
the plurality of inner guard ring buried interconnection lines each having a line shape are disposed adjacent to each other in a first horizontal direction and extend in parallel with each other in a second horizontal direction perpendicular to the first horizontal direction;
the plurality of inner guard ring lower plugs each having a wall shape are disposed adjacent to each other in the first horizontal direction and extend in parallel to each other in the second horizontal direction; and
the inner guard ring top pad having a line shape extends in the second horizontal direction.

5. The semiconductor device of claim 4,
wherein the inner guard ring structure further includes:
an inner guard ring lower pad disposed over the plurality of inner guard ring lower plugs;
a plurality of inner guard ring middle plugs disposed over the inner guard ring lower pad;
an inner guard ring upper pad disposed over the plurality of inner guard ring middle plugs; and
a plurality of inner guard ring upper plugs disposed between the inner guard ring upper pad and the inner guard ring top pad,
wherein the inner guard ring lower pad and the inner guard ring upper pad each having a line shape extend in parallel to each other in the second horizontal direction,
wherein the plurality of inner guard ring middle plugs and the plurality of inner guard ring upper plugs each having a wall shape extend in parallel to each other in the second horizontal direction,
wherein the inner guard ring lower pad connects the plurality of inner guard ring lower plugs to each other in the first horizontal direction, and
wherein the inner guard ring upper pad connects the plurality of inner guard ring middle plugs to each other in the first horizontal direction.

6. The semiconductor device of claim 4, wherein:
the guard ring buried interconnection line further includes a plurality of outer guard ring buried interconnection lines,
the guard ring lower plug further includes a plurality of outer guard ring lower plugs,
the guard ring top pad further includes an outer guard ring top pad,
the guard ring structure further includes an outer guard ring structure including the plurality of outer guard ring buried interconnection lines, the plurality of outer guard ring lower plugs, and the outer guard ring top pad,
the plurality of outer guard ring buried interconnection lines each having a line shape are disposed adjacent to each other in the first horizontal direction and extend in parallel with each other in the second horizontal direction,
the plurality of outer guard ring lower plugs each having a wall shape are disposed adjacent to each other in the first horizontal direction and extend in parallel to each other in the second horizontal direction, and
the outer top guard ring pads each having a line shape extend in the second horizontal direction.

7. The semiconductor device of claim 6,
wherein the outer guard ring structure further includes:
an outer guard ring lower pad disposed over the plurality of outer guard ring lower plugs;
a plurality of outer guard ring middle plugs disposed over the outer guard ring lower pad;
an outer guard ring upper pad disposed over the plurality of outer guard ring middle plugs; and
a plurality of outer guard ring upper plugs disposed between the outer guard ring upper pad and the outer guard ring top pad,
wherein the outer guard ring lower pad and the outer guard ring upper pad each having a line shape extend in parallel to each other in the first horizontal direction,
wherein the outer guard ring lower pad connects the plurality of outer guard ring lower plugs to each other in the first horizontal direction, and
wherein the outer guard ring upper pad connects the plurality of outer guard ring middle plugs to each other in the first horizontal direction.

8. The semiconductor device of claim 6, further comprising a guard ring dummy gate electrode disposed over the substrate between the inner guard ring structure and the outer guard ring structure.

9. The semiconductor device of claim 8, further comprising a peripheral transistor structure disposed in a peripheral circuit area,
wherein the peripheral transistor structure includes:
a peripheral gate electrode disposed over the substrate;
a peripheral lower contact plug disposed over the substrate adjacent to one side of the peripheral gate electrode; and
a peripheral interconnection line disposed over the peripheral lower contact plug,
wherein the plurality of inner guard ring lower plugs, the plurality of outer guard ring lower plugs, and the peripheral lower contact plugs are disposed at a same level based on the substrate,
wherein the inner guard ring top pad, the outer guard ring top pad, and the peripheral interconnection line are disposed at a same level based on the substrate, and
wherein the guard ring dummy gate electrode and the peripheral gate electrode are disposed at a same level based on the substrate to have a same structure.

10. The semiconductor device of claim 9,
wherein the inner guard ring structure further includes inner guard ring support electrodes disposed between the inner guard ring buried interconnection lines and the inner guard ring lower plugs, and
wherein the peripheral gate electrode and the inner guard ring support electrodes are disposed at a same level based on the substrate to have a same structure.

11. The semiconductor device of claim 9,
wherein the outer guard ring structure further includes outer guard ring support electrodes disposed between the outer guard ring buried interconnection lines and the outer guard ring lower plugs, and
wherein the peripheral gate electrode and the outer guard ring support electrodes are disposed at a same level based on the substrate to have a same structure.

12. The semiconductor device of claim 1, further comprising a guard ring shallow trench isolation region disposed in the substrate of the guard ring area to surround the guard ring buried interconnection lines.

13. The semiconductor device of claim 1,
wherein the cell structure further includes:
a bit line contact plug and a storage contact plug disposed over the substrate;
a bit line disposed over the bit line contact plug; and
a storage electrode disposed over the storage contact plug.

14. A semiconductor device comprising:
a cell structure, a peripheral transistor structure, an inner guard ring structure, an outer guard ring structure, and a guard ring dummy gate electrode,
wherein the cell structure includes a buried gate line disposed in a substrate,
wherein the peripheral transistor structure includes:
a peripheral gate electrode disposed over the substrate;
a peripheral lower contact plug disposed over the substrate adjacent to one side of the peripheral gate electrode; and
a peripheral interconnection line disposed over the peripheral lower contact plug,
wherein the inner guard ring structure includes:
inner guard ring buried interconnection lines disposed in the substrate;
inner guard ring lower plugs disposed over the substrate and respectively connected to the inner guard ring buried interconnection lines; and
an inner guard ring top pad disposed over the inner guard ring lower plug and electrically connected to the inner guard ring lower plugs,
wherein the outer guard ring structure includes:
outer guard ring buried interconnection lines disposed in the substrate;
outer guard ring lower plugs disposed over the substrate and respectively connected to the outer guard ring buried interconnection lines; and
an outer guard ring top pad disposed over the outer guard ring lower plugs and electrically connected to the outer guard ring lower plugs,
wherein the guard ring dummy gate electrode is disposed over the substrate between the inner guard ring structure and the outer guard ring structure.

15. The semiconductor device of claim 14,
wherein the inner guard ring buried interconnection lines include:
inner guard ring buried electrodes disposed in lower portions of inner guard ring trenches in the substrate; and
inner guard ring buried capping layers disposed in upper portions of the inner guard ring trenches,
wherein the outer guard ring buried interconnection lines include:
outer guard ring buried electrodes disposed in lower portions of an outer guard ring trenches in the substrate; and
outer guard ring buried capping layers disposed in upper portions of the outer guard ring trenches,
wherein the buried gate line includes:
a buried gate electrode disposed in a lower portion of a buried gate trench in the substrate; and
a buried gate capping layer disposed in an upper portion of the buried gate trench,
wherein the inner guard ring buried electrodes, the outer guard ring buried electrodes, and the buried gate electrode include a same material, and
wherein the inner guard ring buried capping layers, the outer guard ring buried capping layers, and the buried gate capping layer include a same material.

16. The semiconductor device of claim 15,
wherein at least one of the inner guard ring lower plugs corresponds to and vertically penetrates at least one of the inner guard ring buried capping layers and corresponds to and is connected to at least one of the inner guard ring buried electrodes.

17. The semiconductor device of claim 15,
wherein at least one of the outer guard ring lower plugs corresponds to and vertically penetrates at least one of the outer guard ring buried capping layers and corresponds to and is connected to at least one of the outer guard ring buried electrodes.

18. The semiconductor device of claim 15,
wherein the inner guard ring structure further includes inner guard ring support electrodes disposed over the inner guard ring buried interconnection lines,
wherein the inner guard ring lower plugs are respectively connected to the inner guard ring support electrodes.

19. The semiconductor device of claim 15,
wherein the outer guard ring structure further includes outer guard ring support electrodes disposed over the outer guard ring buried interconnection lines,
wherein the outer guard ring lower plugs are respectively connected to the outer guard ring support electrodes.

20. The semiconductor device of claim 14,
wherein the peripheral gate electrode and the guard ring dummy gate electrode are disposed at a same level based on the substrate to have a same structure.

21. The semiconductor device of claim 14,
wherein the cell structure further includes:
a bit line contact plug and a storage contact plug disposed over the substrate;
a bit line disposed over the bit line contact plug; and
a storage electrode disposed over the storage contact plug.
